(19) United States
(12) Patent Application Publication
(10) Pub. No.: US 2002/0123219 A1
(43) Pub. Date: Sep. 5, 2002

(54) Method of forming a via of a dual damascene with low resistance

(76) Inventors: Jerald Laverty, Laverne, OK (US); Ching-Yu Chang, I Lan Hsien (TW); Uway Tseng, Tai-Chung Hsien (TW); Weng-Hsing Huang, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 09/682,481

(22) Filed: Sep. 7, 2001

(30) Foreign Application Priority Data
Mar. 2, 2001 (TW) 090104927

(51) Int. Cl. H01L 21/4763

(52) U.S. Cl. 438/637; 438/638

(57) ABSTRACT

The present invention provides afirst dielectric layer, a stop layer and a second dielectric layer arethen formed on the conductive layer disposed on a semiconductor substrate, respectively. By performing a first lithography/etching process to etch portions of the second dielectric layer in a predetermined area, a wire trench is formed in the predetermined area in the second dielectric layer. A first barrier layer is then formed to cover both a surface of the wire trenchand a surface of the second dielectric layer. By performing a second lithography/etching process to etch through the first barrier layer and the first dielectric layer down to the conductive layer, a via is formed at a bottom of the wire trench. A second barrier layer is formed thereafter to cover both a wall and a bottom of the via, and to cover the first barrier layer. Finally, an etching back process is performed to etch the second barrier layer down to the surface of the conductive layer.

### BACKGROUND OF INVENTION

1. Field of the Invention

The present invention relates to a method of forming a dual damascene structure, and more specifically to a method of forming a via of a dual damascene with low resistance.

2. Description of the Prior Art

A dual damascene process is a method of forming a conductive wire coupled with a via plug. The dual damascene structure is used to connect devices and wires in a semiconductor wafer and is insulated from other devices by inter-layer dielectrics (ILD) around it. Since copper (cu) has developed the feature of low resistance in recent years, the technique of the copper metal dual damascene interconnect in the multi-layer interconnect process has become very important.

Please refer to FIG. 1 of a schematic diagram of a dual damascene structure 11 according to the prior art. As shown in FIG. 1, a semiconductor chip 10 comprises a bottom copper conductive wire 14 inlayed, a first low-k layer 12 and an upper copper conductive wire 24 inlayed, and a trench structure 23 of a second low-k layer. The upper copper conductive wire 24 and the bottom copper conductive wire 14 connect with the barrier layer 18 between the first low-k layer 12 and the second low-k layer 20 through a via 22.

In the method of forming a dual damascene structure 11 according to the prior art, a barrier layer 13 is formed to prevent penetration by copper ions into low-k layers 12 and 20 in subsequent processes. The barrier layer 13, normally comprising of titanium (Ti), titanium nitride (TiN), tantalum nitride (TaN) or tungsten nitride (WN), needs to have at least the following four characteristics:

a. A good ability of preventing ion penetration;

b. A good adhesion ability to both copper and dielectric layers;

c. A resistance no greater than 1000 μΩ-cm; and

d. An excellent step coverage ability.

However, the resistance of the dual damascene structure formed by the method according to the prior art is very high due to the fixed resistance of the barrier layer 13. The performance of the device is thus affected. Besides, the insufficient step coverage ability of portions of the barrier layer 13 within the via 22 normally cause a weak coverage of portions of the barrier layer 13 in the bottom-corner of the dual damascene structure, resulting in an increase in the resistance.

### SUMMARY OF INVENTION

It is therefore a primary object of the present invention to provide a method of forming a via of a dual damascene structure with low resistance so as to prevent effects caused by the high resistance of the interconnection.

According to the claimed invention, a semiconductor substrate, comprising a conductive layer disposed atop a semiconductor substrate, is provided in a method of forming a via of a dual damascene with low resistance. A first dielectric layer, a stop layer and a second dielectric layer are formed on the conductive layer, respectively. By performing a first lithography/etching process to etch portions of the second dielectric layer in a predetermined area, a wire trench is formed in the predetermined area in the second dielectric layer. A first barrier layer is then formed to cover both a surface of the wire trench and a surface of the second dielectric layer. A second lithography/etching process is performed thereafter to etch through the first barrier layer and the first dielectric layer down to the conductive layer so as to form a via at a bottom of the wire trench. A second barrier layer is then formed tocover both a wall and a bottom of the via, and to cover the first barrier layer. Finally, an etching back process is performed to etch the second barrier layer down to the surface of the conductive layer at the end of the method.

It is an advantage of the present invention against the prior art that a via of a dual damascene with low resistance is formed with two barrier layers through simple processes. A spacer is formed on a wall on opposite sides of the via 46 by the remaining portions of the second barrier layer after the etching back process. The penetration by copper ions can thus be prevented so that the reliability of the product is improved. Besides, due to simplified manufacturing processes, the production efficiency is significantly increased.

These and other objectives of the present invention will no doubt become obvious to those of ordinary skill in the art after reading the following detailed description of the preferred embodiment, which is illustrated in the multiple figures and drawings.

### BRIEF DESCRIPTION OF DRAWINGS

FIG. 1 is the schematic diagram of a dual damascene structure 11 according to the prior art.

FIG. 2 to FIG. 7 are the cross-sectional views for forming a via of a dual damascene with low resistance according to the present invention.

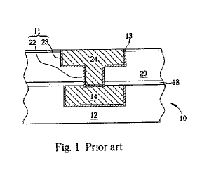

### DETAILED DESCRIPTION

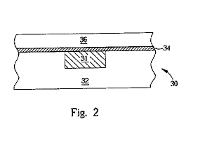

Please refer to FIG. 2 to FIG. 7 of cross-sectional views of forming a via of a dual damascene with low resistance according to the present invention. As shown in FIG. 2, a semiconductor wafer 30 comprises a bottom layer 32, composed of a low k material, a silicon nitride layer 34 covering the surface of the bottom layer 32, and a low k layer 36, having a dielectric constant ranging from 2.6 to 3.2 and a thickness ranging from thousands of angstroms to several micrometers, covering the surface of the silicon nitride layer 34. A conductive layer 31, comprising an underlayer metal line, is buried in the bottom layer 32. The low k layer 36 is normally composed of low k materials, comprising a material having properties consistent with FLARE™, produced by the Allied Signal Company, formed by a spin-on-coating process, or inorganic low k materials, comprising silicon oxide, formed by a chemical vapor deposition (CVD) process. Alternatively, the low k layer 36 is composed of a low k material, comprisingSiLK™ produced by the Schumacher Company,poly(arylene ether) polymer, parylene, polyimide, fluorinated polyimide, HSQ, fluorosilicate glass (FSG), silicon oxide, nanoporous silica, or Teflon®. For simplicity of description, other devices on the semiconductor wafer 30 are omitted in FIG. 2.

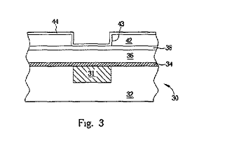

As shown in FIG. 3, a stop layer 38, normally composed of silicon oxide, and a low k layer 42, having a dielectric constant ranging from 2.6 to 3.2 and a thickness ranging from thousands of angstroms to several micrometers,are formed on a surface of the low k layer 36. The low k layer 42 is normally composed of low k materials, comprising a material having the properties consistent with FLARE™, produced by the Allied Signal Company, formed by a spin-on-coating process, or inorganic low k materials, comprising silicon oxide, formed by a CVD process. Alternatively, the low k layer 42 is composed of a low k material, comprisingSiLK™ produced by the Schumacher Company,poly(arylene ether) polymer, parylene, polyimide, fluorinated polyimide, HSQ, FSG, silicon oxide, nanoporous silica, or Teflon®.

A first lithography/etching process is then performed to etch portions of the low k layer 42 in a predetermined area to form a wire trench 43, for containing a dual damascene copper wire in a subsequent process, in the predetermined area in the second dielectric layer. Thereafter, a first barrier layer 44, having a thickness ranging from 200 to 700 angstroms and comprising titanium (Ti), titanium nitride (TiN), tantalum nitride (TaN), titanium tungsten alloy (TiW alloy), tantalum alloy (TaW alloy), silicon nitride, or silicon oxynitride (SiON),is formed to cover both a surface of the wire trench 43 and the low k layer 42. In the preferred embodiment of the present invention, the thickness of the first barrier layer 44 ranges from 350 to 500 angstroms. For simplicity of description, the method of forming the first barrier layer 44, normally a sputtering process or a CVD process based on the composition of the first barrier layer 44, is omitted.

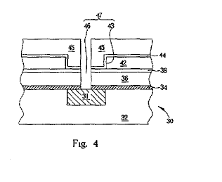

As shown in FIG. 4, a photoresist layer 45 used to define a pattern of a via 46, is coated on the surface of the first barrier layer 44. A second lithography/etching process, using the photoresist layer 45 as a mask, is performed to etch through the first barrier layer 44, stop layer 38, low k layer 36 and the silicon nitride layer 34 down to the conductive layer 31 so as to form the via 36 at a bottom of the wire trench. A dual damascene structure 47 is thus formed by the via 46 and the wire trench 43. As previously mentioned, the second lithography/etching process is performed to etch through the first barrier layer 44, stop layer 38, low k layer 36 and the silicon nitride layer 34. Thus various etching gases are employed and etching parameters are adjusted for the second lithography/etching process. For simplicity of description, the method of changing etching gases and parameters is omitted.

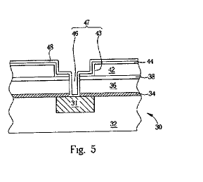

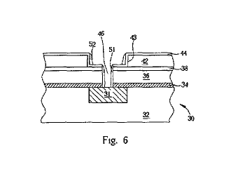

As shown in FIG. 5, a second barrier layer 48, comprising titanium (Ti), titanium nitride (TiN), tantalum nitride (TaN), titanium tungsten alloy (TiW alloy), tantalum alloy (TaW alloy), silicon nitride, or silicon oxynitride (SiON) and having a thickness ranging from 200 to 600 angstroms,is formed to cover both the first barrier layer 44 and the dual damascene structure 47. In the preferred embodiment of the present invention, the thickness of the second barrier layer 48 ranges from 250 to 450 angstroms. The second barrier layer 48 is normally formed by performing a sputtering process or a CVD process, due to the composition of the second barrier layer 48. As shown in FIG. 6, an etching back process is performed to etch the second barrier layer 48 down to the surface of the conductive layer 31. A spacer 51 and a spacer 52 are formed on a wall on opposite sides of the via 46 by the remaining portions of the second barrier layer 48 after the etching back process.

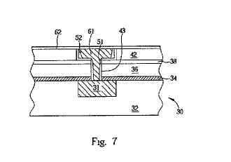

As shown in FIG. 7, a plating process is performed to form a copper layer 61 to fill the dual damascene structure 47, including both the wire trench 43 and the via 46. A chemical mechanical polishing (CMP) process is then performed to remove portions of the copper layer 61. The dual damascene copper wire is thus formed by the remaining portions of the copper layer 61 in the wire trench 43. Finally, a protection layer 62, normally composed of silicon nitride, is formed on the dual damascene copper wire at the end of the method.

In comparison with the prior art, the dual damascene structure in the present invention has a via of a dual damascene with low resistance and two barrier layers. Spacers 51 and 52 are formed on a wall on opposite sides of the via 46 by the remaining portions of the second barrier layer after the etching back process. Thus penetration by the copper ions can be prevented. In addition, the production efficiency is significantly improved due to the simplified manufacturing processes.

Those skilled in the art will readily observe that numerous modifications and alterations of the device may be made while retaining the teachings of the invention. Accordingly, the above disclosure should be construed as limited only by the metes and bound of the appended claims.

what is claimed is:

1. A method of forming a via of a dual damascene with low resistance, the method comprising:
providing a semiconductor substrate, a conductive layer disposed atop the semiconductor substrate;
forming a first dielectric layer on the conductive layer;
forming a stop layer on the first dielectric layer;
forming a second dielectric layer on the stop layer;
performing a first lithography/etching process to etch portions of the second dielectric layer in a predetermined area to form a wire trench in the predetermined area in the second dielectric layer;
forming a first barrier layer to cover both a surface of the wire trench and the second dielectric layer;
performing a second lithography/etching process to etch through the first barrier layer and the first dielectric layer down to the conductive layer so as to form a via at a bottom of the wire trench;
forming a second barrier layer to cover both a wall and a bottom of the via, and to cover the first barrier layer; and
performing an etching back process to etch the second barrier layer down to the surface of the conductive layer.

2. The method of claim 1 wherein the conductive layer is a copper wire.

3. The method of claim 1 wherein a spacer is formed on a wall on opposite sides of the via by the remaining portions of the second barrier layer after the etching back process.

4. The method of claim 1 wherein the first dielectric layer is composed of a low k (low dielectric constant) material.

5. The method of claim 4 wherein the low k material comprises FLARE™, SiLK™, poly (arylene ether) polymer, parylene, polyimide, fluorinated polyimide, HSQ, fluorosilicate glass (FSG), silicon oxide, nanoporous silica, or Teflon.

6. The method of claim 1 wherein the second dielectric layer is composed of a low k (low dielectric constant) material.

7.The method of claim 6 wherein the low k material comprises FLARE™, SiLK™, poly (arylene ether) polymer, parylene, polyimide, fluorinated polyimide, HSQ, fluorosilicate glass (FSG), silicon oxide, nanoporous silica, or Teflon®.

8. The method of claim 1 wherein the first barrier layer comprises titanium (Ti), titanium nitride (TiN), tantalum nitride (TaN), titanium tungsten alloy (TiW alloy), tantalum alloy (TaW alloy), silicon nitride, or silicon oxynitride (SiON).

9. The method of claim 1 wherein the second barrier layer comprises titanium (Ti), titanium nitride (TiN), tantalum nitride (TaN), titanium tungsten alloy (TiW alloy), tantalum alloy (TaW alloy), silicon nitride, or silicon oxynitride (SiON).

10. The method of claim 1 wherein after etching back the second barrier layer, the method further comprises:
performing a plating process to form a copper metal layer to fill both the wire trench and the via;
performing a chemical mechanical polishing (CMP) process to form a dual damascene copper wire in the wire trench; and
forming a protection layer on the dual damascene copper wire.
